(19) United States
(12) Patent Application Publication
(10) Pub. No.: US 2019/0006437 A1
(43) Pub. Date: Jan. 3, 2019

(54) LIGHT EMITTING DEVICE

(71) Applicant: Industrial Technology Research Institute, Hsinchu (TW)

(72) Inventors: Yi-Ping Lin, Hsinchu (TW); Jung-Yu Li, Hsinchu (TW); Guan-Yu Chen, Hsinchu (TW); Shih-Pu Chen, Hsinchu (TW)

(21) Appl. No.: 15/863,512

(22) Filed: Jan. 5, 2018

(30) Foreign Application Priority Data
Jun. 30, 2017 (TW) 106121985

(51) Int. Cl. H01L 27/32; H01L 51/52

(52) U.S. Cl. CPC H01L 27/3216; H01L 27/3246; H01L 27/3283; H01L 27/3218; H01L 51/5225; H01L 51/5209

(57) ABSTRACT

A light emitting device is disclosed and defined with a plurality of light emitting regions. The light emitting device includes a first electrode layer, a second electrode layer, an organic material layer, and an insulating material layer formed between the first and second electrode layers. The light emitting regions are exposed from the insulating material layer, and have different areas. Regions of the first electrode layer corresponding in position to the light emitting regions have the same areas, or regions of the organic material layer corresponding in position to the light emitting regions have the same areas. Voltages applied across the first electrode layer and the second electrode layer corresponding in position to the light emitting regions are the same. The light emitting device displays grayscale or color images.

### CROSS-REFERENCE TO RELATED APPLICATION

The present application is based on, and claims priority from, Taiwan (International) Application Serial Number 106121985, filed Jun. 30, 2017, the disclosure of which is hereby incorporated by reference herein in its entirety.

### TECHNICAL FIELD

The disclosure relates to light emitting devices, and, more particularly, to an organic light emitting diode.

### BACKGROUND

Light emitting diodes (LEDs) involve the use of semiconductor materials that are turned into p-type and n-type semiconductors through doping. These semiconductor materials are joined together to form a p-n junction, and electrons and holes can be injected into the n-type and p-type materials, respectively. When the electrons and holes meet and combine, energy is released in the form of photons.

Organic light emitting diodes (OLEDs) involve the use of organic materials. The emission process of an OLED is briefly as follows: a forward bias is applied, so that the electrons and holes overcome the interface energy barriers are injected from the cathode and anode, respectively. Under the action of the electric field, the electrons and the holes move towards each other and form excitons in a light emitting layer. The electrons and holes are then combined in the light emitting layer, the excitons thus disappear and release light energy.

At present, OLED full-color display are mostly achieved through active matrix OLEDs (AMOLEDs) or passive matrix OLEDs (PMOLEDs). For example, the brightness of each pixel is controlled by individually controlling upper and lower electrodes of each pixel in the PMOLEDs, or thin film transistors (TFTs) in the AMOLEDs.

However, the use of TFT in each pixel to control the voltage so that each pixel produces a different luminous intensity to achieve grayscale/full-color imaging requires complex processes and expensive TFT drive control circuits, so it is unfavorable in developing low-cost manufacturing techniques in the field of OLEDs.

Therefore, there is a need for a solution that addresses the issue that a single voltage cannot be used to display grayscale or full-color images in existing OLEDs.

### SUMMARY

In view of the aforementioned shortcomings of the prior art, the disclosure provides an OLED light emitting device.

In an embodiment, a light emitting device is defined with a plurality of light emitting regions that have different areas. The light emitting device may include: a first electrode layer; a second electrode layer formed above the first electrode layer; an organic material layer formed between the first electrode layer and the second electrode layer; and an insulating material layer formed between the first electrode layer and the second electrode layer and disposed around a periphery of the light emitting regions being exposed, wherein regions in the first electrode layer corresponding in position to the light emitting regions have the same areas, or regions in the organic material layer corresponding in position to the light emitting regions have the same areas.

In another embodiment, a light emitting device is defined with a plurality of pixels, and each of the pixels includes a plurality of light emitting regions that have different areas. The light emitting device may include: a first electrode layer; a second electrode layer formed above the first electrode layer; an organic material layer formed between the first electrode layer and the second electrode layer and including a plurality of discrete organic material bumps corresponding in positions to the plurality of light emitting regions; and an insulating material layer formed between the first electrode layer and the second electrode layer and between the organic material bumps and disposed around a periphery of the light emitting regions being exposed, wherein regions in the first electrode layer corresponding in position to the light emitting regions have the same areas, or regions in the organic material layer corresponding in position to the light emitting regions have the same areas.

### BRIEF DESCRIPTION OF THE DRAWINGS

FIG. 1 is a cross-sectional schematic diagram of an embodiment of a light emitting device according to the disclosure;

FIG. 2 is a cross-sectional schematic diagram of an embodiment of a light emitting device according to the disclosure;

FIG. 3 is a cross-sectional schematic diagram of an embodiment of a light emitting device according to the disclosure;

FIG. 4 is a cross-sectional schematic diagram of an embodiment of a light emitting device according to the disclosure;

FIG. 5 is a cross-sectional schematic diagram of an embodiment of a light emitting device according to the disclosure;

FIG. 6 is a cross-sectional schematic diagram of an embodiment of a light emitting device according to the disclosure;

FIG. 7 is a cross-sectional schematic diagram of an embodiment of a light emitting device according to the disclosure;

FIG. 8 is a cross-sectional schematic diagram of an embodiment of a light emitting device according to the disclosure;

FIG. 9 is a cross-sectional schematic diagram of an embodiment of a light emitting device according to the disclosure;

FIG. 10 is a cross-sectional schematic diagram of an embodiment of a light emitting device according to the disclosure;

FIG. 11 is a planar schematic diagram of an embodiment of a light emitting device according to the disclosure; and

FIG. 12 is a planar schematic diagram of an embodiment of a light emitting device according to the disclosure.

### DETAILED DESCRIPTION

The disclosure is described by the following specific embodiments. Those with ordinary skills in the arts can readily understand other advantages and functions of the disclosure after reading the disclosure of this specification. The disclosure may also be practiced or applied with other different implementations. Based on different contexts and applications, the various details in this specification can be modified and changed without departing from the spirit of the disclosure.

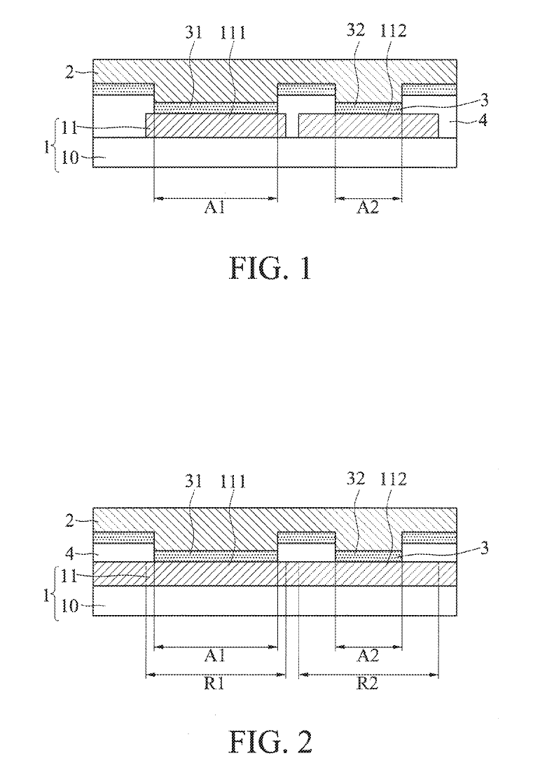

Referring to FIGS. 1 to 6, a light emitting device according to the disclosure is defined with a plurality of light emitting regions A1 and A2, and includes a first electrode layer 1, a second electrode layer 2, and an organic material layer 3 and an insulating material layer 4 formed between the first electrode layer 1 and the second electrode layer 2.

The plurality (two are shown in FIGS. 1 to 6) of light emitting regions A1 and A2 have different areas. A light emitting region in the disclosure is defined as the smaller one of the contact areas of the organic material layer 3 with the first electrode layer 1 and the second electrode layer 2.

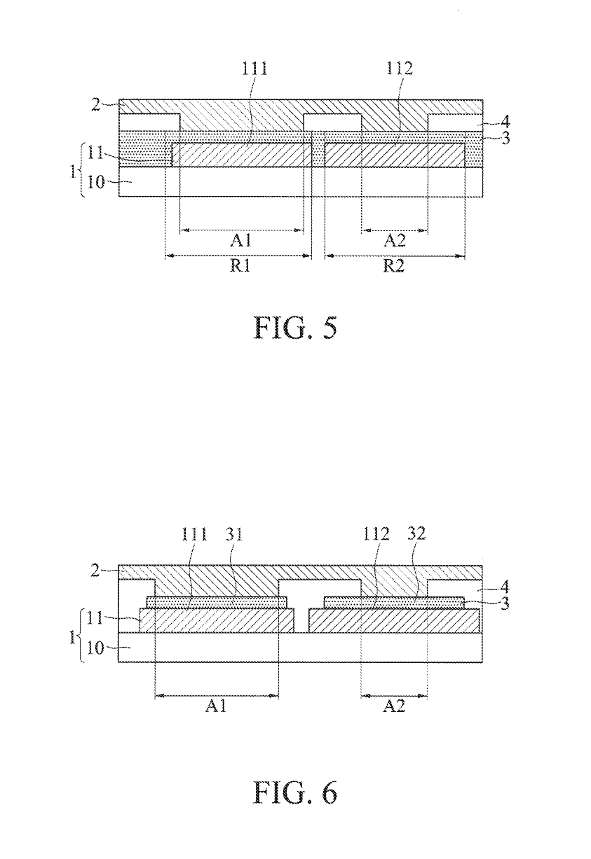

The first electrode layer 1 includes a substrate 10 and an electrode material layer 11 formed thereon. In an embodiment of the disclosure, such as those shown in FIGS. 1, 5 and 6, the electrode material layer 11 includes a plurality of discrete electrode material bumps 111 and 112 partially covering the substrate 10, wherein the areas of the electrode material bumps 111 and 112 in FIG. 1 are the same, and the areas of the electrode material bumps 111 and 112 are the same (e.g., FIG. 5) or different (FIG. 6). In another embodiment of the disclosure, such as those shown in FIGS. 2-4, the electrode material layer 11 covers the entire substrate 10. The substrate 10 can be made of glass, plastic or a semiconductor material, such as silicon or silicide. The electrode material layer 11 can be made of electrically conductive metal oxide, such as indium tin oxide (ITO) or indium zinc oxide (IZO).

The second electrode layer 2 is formed above the first electrode layer 1 and separated from the first electrode layer 1. The second electrode layer 2 can be made of metal or metal alloy, such as Ag, Al, Al/LiF, Ag/Al/Ag, Ag/Ge/Ag, or metal oxide, such as BCP/V₂O₅ [symbol] MoO₃ [symbol] ZnS/Ag/ZnO/Ag [symbol] ZnPc/C₆₀.

The first electrode layer 1 can be one of anode and cathode, and the second electrode layer 2 can be the other one of anode and cathode.

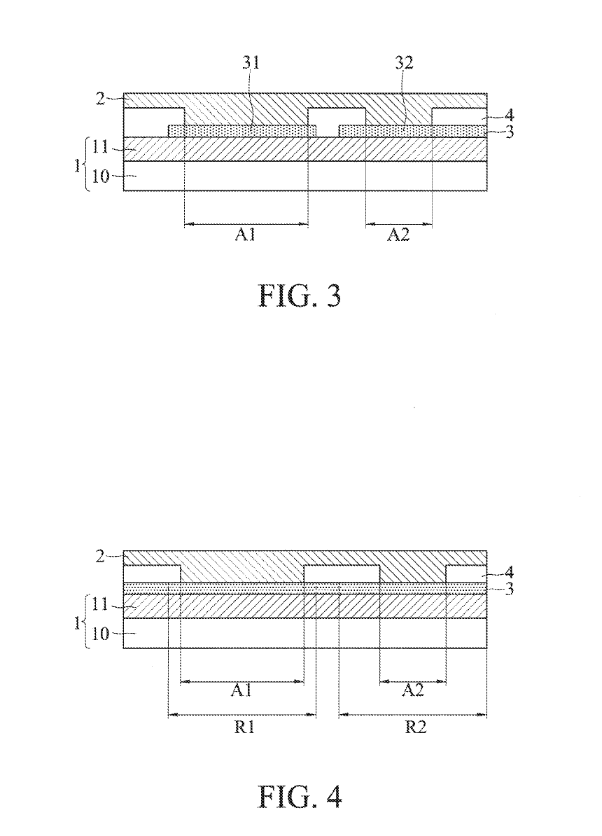

The organic material layer 3 is formed between the first electrode layer 1 and the second electrode layer 2. As shown in FIGS. 1-3 and 6, the organic material layer 3 includes a plurality of discrete organic material bumps 31 and 32 partially covering the first electrode layer 1. Furthermore, in FIG. 1 and FIG. 2, the areas of organic material bumps 31 and 32 are different, in FIG. 3 and FIG. 6, the areas of organic material bumps 31 and 32 are the same. As shown in FIGS. 4 and 5, the organic material layer 3 covers the entire first electrode layer 1. The organic material layer 3 can be made of a fluorescent or phosphorescent material, for example, green phosphorescent 24 FT Ir (acac) material. The organic material layer 3 may further include a hole injection layer (HIL), a hole transport layer (HTL), an emitting layer (EL), an electron transport layer (ETL), and an electron injection layer (EIL). The organic material layer 3 may not include the emitting layer, but, instead, a hole transport material and an electron transport material that are in contact and interact with each other to generate exciplex capable of emitting light.

The insulating material layer 4 is formed between the first electrode layer 1 and the second electrode layer 2 and around the peripheries of the plurality of light emitting regions A1 and A2 that have different areas to allow the light emitting regions A1 and A2 to emit light under a voltage. In FIGS. 1 and 2, the insulating material layer 4 covers portions of the first electrode layer 1 (the electrode material bumps 111 and the 112 shown in FIG. 1 or the electrode material layer 11 shown in FIG. 2) and exposes a plurality of surfaces that do not have the same areas to allow the plurality of organic material bumps 31 and 32 to be formed on the plurality of exposed surfaces of the first electrode layer 1, and the insulating material layer 4 is further formed between the discrete organic material bumps 31 and 32. In FIGS. 3-6, the insulating material layer 4 is formed between the organic material layer 3 and the second electrode layer 2 to cover portions of the organic material layer 3 (e.g., the organic material bumps 31 and 32 shown in FIGS. 3 to 6 and the organic material layer 3 shown in FIGS. 4 and 5) and expose a plurality of surfaces that have different areas to allow the second electrode layer 2 to be formed on the plurality of exposed surfaces of the organic material layer 3 and the insulating material layer 4. The insulating material layer 4 in FIGS. 3-6 is further formed between the discrete organic material bumps 31 and 32. Moreover, as shown in FIGS. 1 and 6, the insulating material layer 4 is further formed between the discrete electrode material bumps 111 and 112. The insulating material layer 4 can be a photoresist layer, a patterned insulating material layer or a laser inkjet paste.

Referring to FIG. 1, an embodiment is disclosed where a region of the first electrode layer 1 corresponding in position to the light emitting region A1 and a region of the first electrode layer 1 corresponding in position to the light emitting region A2 have the same areas. The first electrode layer 1 includes the substrate 10 and the electrode material layer 11. The electrode material layer 11 includes a plurality of electrode material bumps 111 and 112 that have the same areas and are separated by the insulating material layer 4. Each region of the first electrode layer 1 corresponding in position to the light emitting region A1 or the light emitting region A2 is the same. In other words, a region of the electrode material layer 11 corresponding in position to the light emitting region A1 and a region of the electrode material layer 11 corresponding in position to the light emitting region A2 have the same areas. The regions of the first electrode layer 1 corresponding in positions to the light emitting regions A1 and A2 are the electrode material bumps 111 and 112, respectively. The insulating material layer 4 covers portions of the electrode material layer 11 and exposes a plurality of surfaces of the electrode material layer 11 of the first electrode layer 1 that have different areas, such that the organic material layer 3 can be formed on the exposed surfaces of the electrode material layer 11, so that the organic material layer 3 becomes a plurality of organic material bumps 31 and 32 that have different areas and are separated by the insulating material layer 4. The exposed surfaces that have different areas of the electrode material bumps 111 and 112 of the same area of the electrode material layer 11 are thus in contact with the plurality of organic material bumps 31 and 32, thereby forming the light emitting regions A1 and A2 that have different areas. In addition, during coating of the organic material layer 3, the insulating material layer 4 and the first electrode layer 1 are generally coated with the organic material layer 3, so that the organic material layer 3 can be formed between the insulating material layer 4 and the second electrode layer 2 and between the first electrode layer 1 and the second electrode layer 2.

Referring to FIG. 2, an embodiment is disclosed where regions R1 and R2 of the first electrode layer 1 corresponding in positions to the light emitting region A1 and the light emitting region A2 have the same areas. The first electrode layer 1 includes the substrate 10 and the electrode material layer 11. The electrode material layer 11 covers the entire substrate 10. The insulating material layer 4 covers portions of the electrode material layer 11 and exposes a plurality of surfaces of the electrode material layer 11 that have different areas for forming the organic material layer 3 thereon, so that the organic material layer 3 becomes a plurality of organic material bumps 31 and 32 that have different areas and are separated by the insulating material layer 4. The exposed surfaces that have different areas of the same-area regions R1 and R2 of the electrode material layer 11 are in contact with the plurality of organic material bumps 31 and 32, thereby forming the light emitting regions A1 and A2 that have different areas. In addition, during coating of the organic material layer 3, the insulating material layer 4 and the first electrode layer 1 are generally coated with the organic material layer 3, so that the organic material layer 3 can be formed between the insulating material layer 4 and the second electrode layer 2 and between the first electrode layer 1 and the second electrode layer 2.

Referring to FIG. 3, an embodiment is disclosed where each region of the organic material layer 3 corresponding in position to the light emitting region A1 or the light emitting region A2 has the same area. The organic material layer 3 includes a plurality of organic material bumps 31 and 32 that have the same areas and are separated by the insulating material layer 4. The regions of the organic material layer 3 corresponding in positions to the light emitting region A1 and the light emitting region A2 are the organic material bumps 31 and 32, respectively. The electrode material layer 11 covers the entire substrate 10. The insulating material layer 4 covers portions of the organic material layer 3 and exposes a plurality of surfaces of the organic material layer 3 that have different areas for forming the second electrode layer 2 thereon, such that the plurality of exposed surfaces of the organic material layer 3 that have different areas are in contact with the second electrode layer 2 to form the plurality of light emitting regions A1 and A2 that have different areas.

Referring to FIG. 4, an embodiment is disclosed where regions R1 and R2 of the organic material layer 3 corresponding in positions to the light emitting regions A1 and A2 have the same areas. The organic material layer 3 covers the entire first electrode layer 1, and the electrode material layer 11 covers the entire substrate 10. The insulating material layer 4 covers portions of the organic material layer 3 and exposes a plurality of surfaces of the organic material layer 3 that have different areas for forming the second electrode layer 2 thereon, such that the plurality of exposed surfaces of the organic material layer 3 that have different areas are in contact with the second electrode layer 2 to form the plurality of light emitting regions A1 and A2 that have different areas.

Referring to FIG. 5, an embodiment is disclosed where regions R1 and R2 of the organic material layer 3 corresponding in positions to the light emitting region A1 or the light emitting region A2 have the same areas. The organic material layer 3 covers the entire first electrode layer 1, and the electrode material layer 11 includes a plurality of discrete electrode material bumps 111 and 112. The insulating material layer 4 covers portions of the organic material layer 3 and exposes a plurality of surfaces of the organic material layer 3 that have different areas for forming the second electrode layer 2 thereon, such that the plurality of exposed surfaces of the organic material layer 3 that have different areas are in contact with the second electrode layer 2 to form the plurality of light emitting regions A1 and A2 that have different areas.

Referring to FIG. 6, an embodiment is disclosed where each region of the organic material layer 3 corresponding in position to the light emitting region A1 or the light emitting region A2 has the same area. The organic material layer 3 includes a plurality of organic material bumps 31 and 32 that have the same areas and are separated by the insulating material layer 4. The regions of the organic material layer 3 corresponding in positions to the light emitting region A1 and the light emitting region A2 are the organic material bumps 31 and 32, respectively. The electrode material layer 11 includes a plurality of electrode material bumps 111 and 112 that are separated by the insulating material layer 4. The insulating material layer 4 covers portions of the organic material layer 3 and exposes a plurality of surfaces of the organic material layer 3 that have different areas for forming the second electrode layer 2 thereon, such that the plurality of exposed surfaces of the organic material layer 3 that have different areas are in contact with the second electrode layer 2 to form the plurality of light emitting regions A1 and A2 that have different areas.

In the above embodiments with respect to FIGS. 1-6, a voltage applied across the first electrode layer and the second electrode layer at a position corresponding to the light emitting region A1 is the same as a voltage applied across the first electrode layer and the second electrode layer at a position corresponding to the light emitting region A2. In other words, the light emitting device according to the disclosure doesn't require TFT or other similar elements to control the voltage of each light emitting region as the voltages applied to all of the light emitting regions are the same according to the disclosure. Moreover, the regions R1 and R2 in the organic material layer 3 corresponding in positions to the light emitting regions A1 and A2 or the organic material bumps 31 and 32 include the same organic materials, so the light emitting device according to the disclosure is capable of displaying monochrome grayscale images. For example, if the material used for the organic material layer 3 is a green luminescent material, the light emitting device according to the disclosure is capable of displaying green grayscale images. In other words, light emitting regions with larger areas emit brighter (lighter) green colors, while light emitting regions with smaller areas emit dimmer (darker) green colors.

Therefore, the light emitting device according to the disclosure may include regions in the first electrode layer corresponding in positions to the light emitting regions that have the same areas, or regions in the organic material layer corresponding in positions to the light emitting regions that have the same areas, and a plurality of light emitting regions that have different areas can be provided by using the insulating material layer to expose surfaces of the first electrode layer or surfaces of the organic material layer that have different areas, thereby achieving monochrome grayscale images.

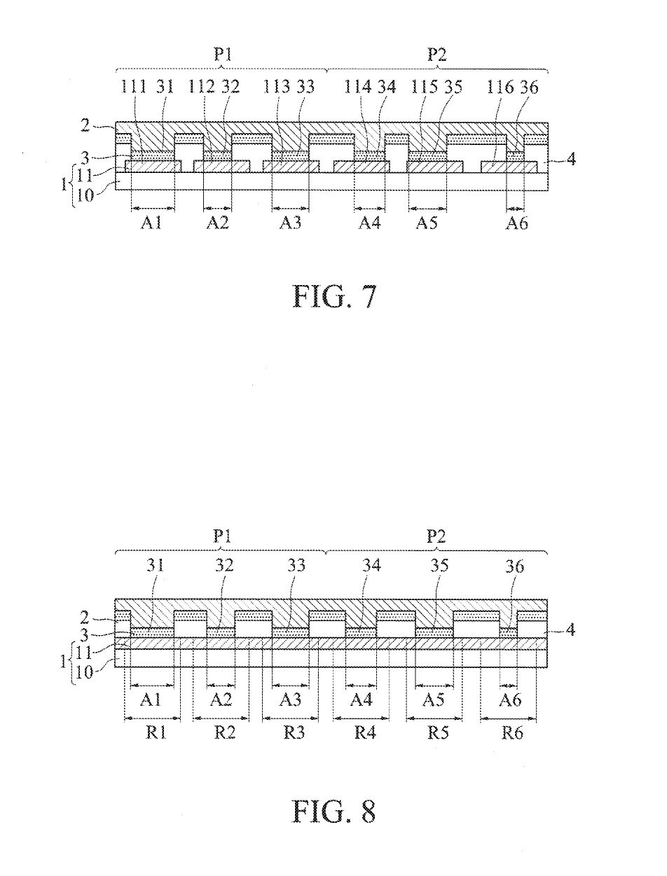

Referring to FIGS. 7-10, a light emitting device according to the disclosure is defined with a plurality of pixels P1 and P2, and includes a first electrode layer 1, a second electrode layer 2 and an organic material layer 3 and an insulating material layer 4 formed between the first electrode layer 1 and the second electrode layer 2.

A pixel P1 includes a plurality of (e.g., three) light emitting regions A1, A2 and A3. A pixel P2 includes a plurality of (e.g., three) light emitting regions A4, A5 and A6, and the light emitting regions A1, A2, A3, A4, A5 and A6 have different areas.

The materials and functionalities of the first electrode layer 1, the second electrode layer 2, the organic material layer 3 and the insulating material layer 4 are similar to those of the embodiments described with respect to FIGS. 1-6. Various embodiments of the light emitting device according to the disclosure are shown in FIGS. 7 to 10 and described as follow.

Referring to FIG. 7, regions in the first electrode layer 1 corresponding in position to the light emitting regions A1, A2, A3, A4, A5 and A6 have the same areas. The electrode material layer 11 includes a plurality of electrode material bumps 111, 112, 113, 114, 115 and 116 that have the same areas and are separated by the insulating material layer 4. The regions in the first electrode layer 1 corresponding in position to the light emitting regions A1, A2, A3, A4, A5 and A6 are also corresponding to the electrode material bumps 111, 112, 113, 114, 115 and 116, respectively. The insulating material layer 4 covers portions of the first electrode layer 1 and exposes a plurality of surfaces of the first electrode layer 1 that have different areas for the organic material layer 3 to be formed thereon, such that the organic material layer 3 becomes a plurality of organic material bumps 31, 32, 33, 34, 35 and 36 that have different areas and are separated by the insulating material layer 4. The exposed surfaces of the first electrode layer 1 that have different areas are in contact with the plurality of organic material bumps 31, 32, 33, 34, 35 and 36, thereby forming the light emitting regions A1, A2, A3, A4, A5 and A6 that have different areas. In addition, during coating of the organic material layer 3, the insulating material layer 4 and the first electrode layer 1 are generally coated with the organic material layer 3, so that the organic material layer 3 can be formed between the insulating material layer 4 and the second electrode layer 2 and between the first electrode layer 1 and the second electrode layer 2.

Referring to FIG. 8, regions R1, R2, R3, R4, R5 and R6 of the first electrode layer 1 corresponding in positions to the light emitting regions A1, A2, A3, A4, A5 and A6 have the same areas. The electrode material layer 11 covers the entire substrate 10. The insulating material layer 4 covers portions of the first electrode layer 1 and exposes a plurality of surfaces of the first electrode layer 1 that have different areas for the organic material layer 3 to be formed thereon, so that the organic material layer 3 becomes a plurality of organic material bumps 31, 32, 33, 34, 35 and 36 that have different areas and are separated by the insulating material layer 4. The exposed surfaces of the first electrode layer 1 that have different areas are in contact with the plurality of organic material bumps 31, 32, 33, 34, 35 and 36, thereby forming the light emitting regions A1, A2, A3, A4, A5 and A6 that have different areas. In addition, during coating of the organic material layer 3, the insulating material layer 4 and the first electrode layer 1 are generally coated with the organic material layer 3, so that the organic material layer 3 can be formed between the insulating material layer 4 and the second electrode layer 2 and between the first electrode layer 1 and the second electrode layer 2.

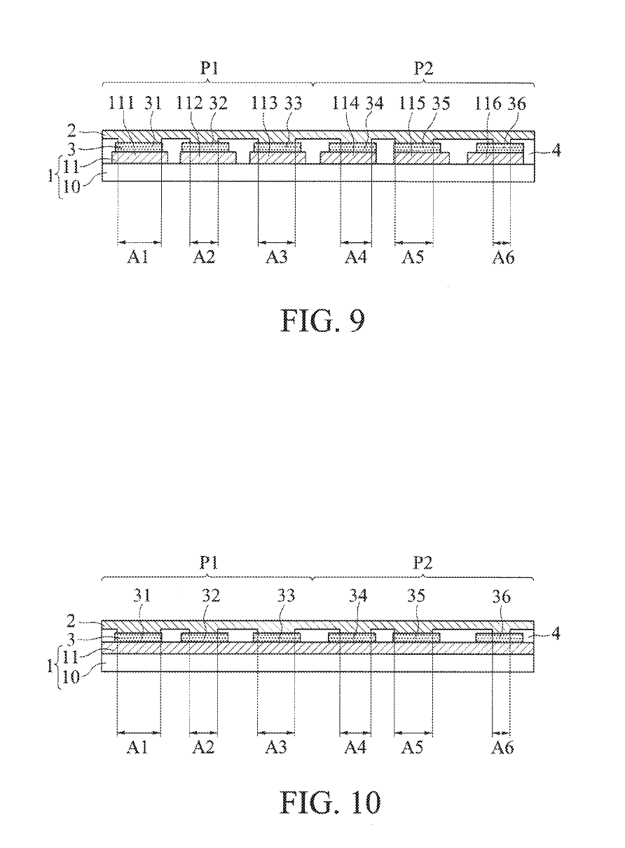

Referring to FIG. 9, a plurality of organic material bumps 31, 32, 33, 34, 35 and 36 corresponding in positions to the light emitting region A1, A2, A3, A4, A5 and A6 have the same areas, and the electrode material layer 11 includes a plurality of electrode material bumps 111, 112, 113, 114, 115 and 116 that are separated by the insulating material layer 4. The insulating material layer 4 covers portions of the organic material layer 3 and exposes a plurality of surfaces of the organic material layer 3 that have different areas for the second electrode layer 2 to be formed thereon. The exposed surfaces of the organic material layer 3 that have different areas are in contact with the second electrode layer 2, thereby forming the plurality of light emitting regions A1, A2, A3, A4, A5 and A6 that have different areas.

Referring to FIG. 10, a plurality of organic material bumps 31, 32, 33, 34, 35 and 36 corresponding in positions to the light emitting region A1, A2, A3, A4, A5 and A6 have the same areas, and the electrode material layer 11 covers the entire substrate 10. The insulating material layer 4 covers portions of the organic material layer 3 and exposes a plurality of surfaces of the organic material layer 3 that have different areas for the second electrode layer 2 to be formed thereon. The exposed surfaces of the organic material layer 3 that have different areas are in contact with the second electrode layer 2, thereby forming the plurality of light emitting regions A1, A2, A3, A4, A5 and A6 that have different areas.

In the embodiments described with respect to FIGS. 7 to 10, a voltage provided across the first electrode layer and the second electrode layer at a position corresponding to the light emitting region A1 is the same as a voltage provided across the first electrode layer and the second electrode layer at a position corresponding to the light emitting region A2, and they are the same as the voltages provided to the light emitting regions A3, A4, A5 and A6. In other words, the light emitting device according to the disclosure requires no TFT or other similar element to control the voltage of each light emitting region as the voltages provided to all of the light emitting regions are the same according to the disclosure.

Moreover, the plurality of organic material bumps 31, 32, 33, 34, 35 and 36 in the pixels P1 and P2 may include different organic materials. For example, the organic material bumps 31 and 34 of the organic material layer 3 may use red luminescent materials, wherein the area of the light emitting region A1 is greater than that of the light emitting region A4, so a brighter red can be emitted by the light emitting region A1; the organic material bumps 32 and 35 of the organic material layer 3 may use green luminescent materials, wherein the area of the light emitting region A2 is smaller than that of the light emitting region A5, so a dimmer green can be emitted by the light emitting region A2; and the organic material bumps 33 and 36 of the organic material layer 3 may use blue luminescent materials, wherein the area of the light emitting region A3 is greater than that of the light emitting region A6, so a brighter blue can be emitted by the light emitting region A3. Therefore, the light emitting device according to the disclosure is capable of display color images.

Moreover, the area of each light emitting region is associated with a maximum area. This maximum area is related to the luminous intensity and luminous efficiency of an organic material bump corresponding to a particular light emitting region. More specifically, the chromaticity coordinates of a white balance required is first determined, such as CIE(X₀, Y₀), and then the coordinates of the three primary colors, Red (R), Green (G) and Blue (B), on the chromaticity coordinates are calculated under the determined white balance. The maximum area of a light emitting region is proportional to the chromaticity coordinates of the R, G and B colors determined, and inversely proportional to the luminous efficiency of the materials of the R, G and B colors. Thus, the area of a monochrome light emitting region can be represented by the follow equation:

Area=(Scale/256)×Amax (1)

wherein Scale/256 is the required color scale, 256 indicates there are 256 colors in 8-bit color depth. More colors can be displayed with more bits in the color depth as needed. Therefore, the area of each light emitting region of the light emitting device of the disclosure is related to the color scale of a single color and the luminous intensity and luminous efficiency of the monochrome organic material.

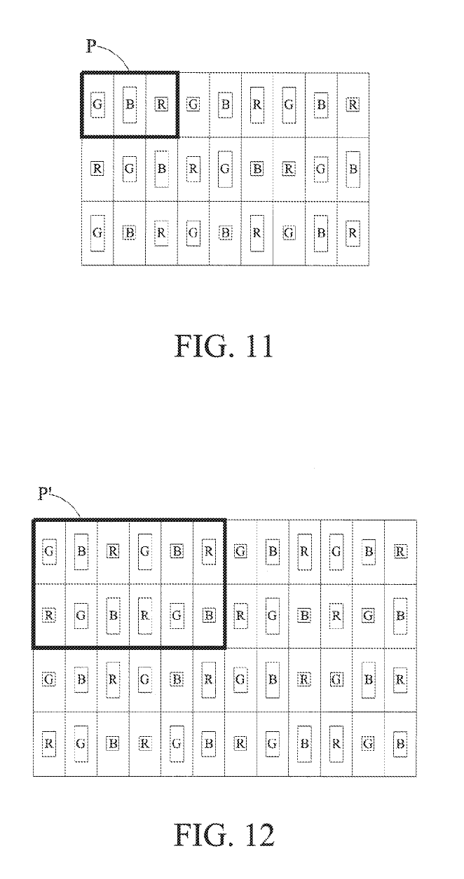

Referring to FIGS. 11 and 12, planar schematic diagrams of embodiments of the light emitting device according to the disclosure are shown. The light emitting device includes a plurality of pixels, each of the pixels including a plurality of light emitting regions that have different areas. Each of the light emitting regions emits red, green or blue color, and, similar to FIGS. 7 and 8, the electrode material bumps in the first electrode layer corresponding in positions to the light emitting regions (or regions in the first electrode layer corresponding to the light emitting regions) have the same areas, or, similar to FIGS. 9 and 10, the organic material bumps in the organic material layer corresponding in positions to the light emitting regions have the same areas.

In FIG. 11, a pixel P includes a set of R, G, B light emitting regions, and equation (1) can be used to calculate the areas of the R, G and B light emitting regions. In FIG. 12, a pixel P′ includes four sets of R, G and B light emitting regions. The total area of the four R light emitting regions can be calculated using equation (1); similarly, the total area of the four G light emitting regions can be calculated using equation (1); and the total area of the four B light emitting regions can be calculated using equation (1).

In conclusion, the light emitting device according to the disclosure uses the insulating material layer to cover portions of the first electrode layer or portions of the organic material layer in order to expose a plurality of light emitting regions that have different areas. The regions of the first electrode layer corresponding in positions to the light emitting regions or the regions of the organic material layer corresponding in positions to the light emitting regions have the same areas. As such, the brightness of light emitted by the light emitting regions can be controlled even though the light emitting regions receive the same voltage, thereby achieving the display of grayscale or full-color images.

The above embodiments are only used to illustrate the principles of the disclosure, and should not be construed as to limit the disclosure in any way. The above embodiments can be modified by those with ordinary skill in the art without departing from the scope of the disclosure as defined in the following appended claims.

What is claimed is:

1. A light emitting device, comprising:
a plurality of light emitting regions having different areas;
a first electrode layer;
a second electrode layer formed above the first electrode layer;
an organic material layer formed between the first electrode layer and the second electrode layer; and
an insulating material layer formed between the first electrode layer and the second electrode layer and disposed around a periphery of the light emitting regions being exposed,
wherein regions in the first electrode layer corresponding in position to the light emitting regions have the same areas, or regions in the organic material layer corresponding in position to the light emitting regions have the same areas.

2. The light emitting device of claim 1, wherein the regions in the first electrode layer corresponding in position to the light emitting regions have the same areas, and the insulating material layer covers portions of the first electrode layer and exposes a plurality of surfaces of the first electrode layer that have different areas for the organic material layer to be formed thereon in order to form organic material bumps that have different areas and separated by the insulating material layer, such that the exposed surfaces of the first electrode layer that have different areas are in contact with the organic material bumps to form the light emitting regions that have different areas.

3. The light emitting device of claim 2, wherein the first electrode layer includes a substrate and an electrode material layer formed on the substrate, and the electrode material layer covers the entire substrate or is a plurality of discrete electrode material bumps that have the same areas.

4. The light emitting device of claim 1, wherein the regions in the organic material layer corresponding in position to the light emitting regions have the same areas, and the insulating material layer covers portions of the organic material layer and exposes a plurality of surfaces of the organic material layer that have different areas for the second electrode layer to be formed thereon, such that the surfaces of the organic material layer that have different areas are in contact with the second electrode layer to form the light emitting regions that have different areas.

5. The light emitting device of claim 4, wherein the organic material layer covers the entire first electrode layer or is composed of a plurality of discrete organic material bumps that have the same areas.

6. The light emitting device of claim 5, wherein the first electrode layer includes a substrate and an electrode material layer formed on the substrate, and the electrode material layer covers the entire substrate or is a plurality of discrete electrode material bumps.

7. The light emitting device of claim 1, wherein voltages applied across the first electrode layer and the second electrode layer at a position corresponding to the light emitting regions are the same.

8. The light emitting device of claim 1, wherein the regions in the organic material layer corresponding in position to the light emitting regions include the same organic material.

9. The light emitting device of claim 1, wherein the light emitting device displays grayscale images.

10. The light emitting device of claim 1, wherein the first electrode layer acts as one of an anode and a cathode, the second electrode layer acts as the other one of the anode and the cathode, the organic material layer includes a hole injection layer (HIL), a hole transport layer (HTL), an emitting layer (EL), an electron transport layer (ETL), and an electron injection layer, or includes a hole transport material and an electron transport material, and the insulating material layer is a photoresist layer, a patterned insulating material layer or a laser inkjet paste.

11. A light emitting device defined with a plurality of pixels, each of the pixels including a plurality of light emitting regions that have different areas, the light emitting device comprising:
a first electrode layer;
a second electrode layer formed above the first electrode layer;
an organic material layer formed between the first electrode layer and the second electrode layer and including a plurality of discrete organic material bumps corresponding in positions to the light emitting regions; and
an insulating material layer formed between the first electrode layer and the second electrode layer and between the organic material bumps, and disposed around a periphery of the light emitting regions being exposed,
wherein regions in the first electrode layer corresponding in position to the light emitting regions have the same areas, or regions in the organic material layer corresponding in position to the light emitting regions have the same areas.

12. The light emitting device of claim 11, wherein the regions in the first electrode layer corresponding in position to the light emitting regions have the same areas, and the insulating material layer covers portions of the first electrode layer and exposes a plurality of surfaces of the first electrode layer that have different areas for the organic material layer to be formed thereon, such that the organic material bumps have different areas, and the exposed surfaces of the first electrode layer that have different areas are in contact with the organic material bumps to form the light emitting regions that have different areas.

13. The light emitting device of claim 12, wherein the first electrode layer includes a substrate and an electrode material layer formed on the substrate, and the electrode material layer covers the entire substrate or is a plurality of discrete electrode material bumps that have the same areas.

14. The light emitting device of claim 11, wherein the regions in the organic material layer corresponding in position to the light emitting regions have the same areas, and the insulating material layer covers portions of the organic material layer and exposes a plurality of surfaces of the organic material bumps that have different areas for the second electrode layer to be formed on the exposed surfaces of the organic material bumps that have different areas, such that the exposed surfaces of the organic material bumps that have different areas are in contact with the second electrode layer to form the light emitting regions that have different areas.

15. The light emitting device of claim 14, wherein the first electrode layer includes a substrate and an electrode material layer formed on the substrate, and the electrode material layer covers the entire substrate or is a plurality of discrete electrode material bumps.

16. The light emitting device of claim 11, wherein voltages applied across the first electrode layer and the second electrode layer at a position corresponding to the light emitting regions are the same.

17. The light emitting device of claim 11, wherein each of the pixels includes a plurality of organic material bumps that have different organic materials.

18. The light emitting device of claim 11, wherein the light emitting device displays color images.

19. The light emitting device of claim 11, wherein the area of each of the light emitting region is associated with a maximum area that is related to a luminous intensity and a luminous efficiency of an organic material bump corresponding to the light emitting region.

20. The light emitting device of claim 11, wherein the first electrode layer acts as one of an anode and a cathode, the second electrode layer acts as the other one of the anode and the cathode, the organic material layer includes a hole injection layer (HIL), a hole transport layer (HTL), an emitting layer (EL), an electron transport layer (ETL), and an electron injection layer, or includes a hole transport material and an electron transport material, and the insulating material layer is a photoresist layer, a patterned insulating material layer or a laser inkjet paste.
